(19) United States
(12) Patent Application Publication
(10) Pub. No.: US 2010/0044890 A1
(43) Pub. Date: Feb. 25, 2010

(54) SEMICONDUCTOR SUBSTRATE MANUFACTURE APPARATUS, SEMICONDUCTOR SUBSTRATE MANUFACTURE METHOD, AND SEMICONDUCTOR SUBSTRATE

(76) Inventors: Hideo Ochi, Saitama (JP); Atsushi Yoshizawa, Saitama (JP); Hideo Satoh, Saitama (JP); Tashaki Chuman, Saitama (JP); Satoru Ohta, Saitama (JP); Chihiro Harada, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/450,229

(22) PCT Filed: Mar. 22, 2007
(86) PCT No.: PCT/JP2007/055877

§ 371 Date: Sep. 17, 2009

(51) Int. Cl. H01L 21/66; G21K 5/10; H01L 23/544

(52) U.S. Cl. 257/797; 250/492.22; 438/16; 257/E23.179; 257/E21.529

(57) ABSTRACT

[Problems] To perform predetermined processing such as annealing and coating application of a semiconductor material with high accuracy on a number of semiconductor formation areas formed over a wide region on a surface of a substrate having elasticity such as a plastic substrate even when the substrate expands and contracts.

[Solving Means] A semiconductor substrate manufacture apparatus includes: a tracking device (33) having a light-emitting portion (34) which applies light to a substrate surface during tracking, a light-receiving portion (35) which receives the light applied by the light-emitting portion (34) and reflected by the substrate surface, and a position detecting portion (36) which detects the positions of the semiconductor formation areas on the substrate based on the spectrum or intensity of the received light; and a semiconductor processing device for performing the predetermined processing on each of the semiconductor formation areas based on position information from the tracking device (33). For example, an annealing light application device (37) or an inkjet nozzle (41) is used as the semiconductor processing device.

### TECHNICAL FIELD

The present invention relates to a semiconductor substrate manufacture apparatus, a semiconductor substrate manufacture method, and a semiconductor substrate, in which predetermined processing is performed on numerous semiconductor formation areas formed over a wide region on a substrate having elasticity such as a plastic substrate.

### BACKGROUND ART

For manufacturing a semiconductor substrate by forming a semiconductor portion on a substrate, various processes are typically performed such as a cleaning process, an electrode-line wiring process, an insulating-film forming process, and a semiconductor burning process. When the substrate is formed of a glass substrate or a silicon wafer, no serious problems arise. When the substrate is formed of a plastic substrate, however, a problem arises in which the substrate expands and contracts at each process. Depending on the material, a substrate having high elasticity may change in size approximately 0.1% of the length of the side of the substrate, and a large substrate measuring several tens of centimeters or more per side may warp as much as approximately 100 μm as a whole.

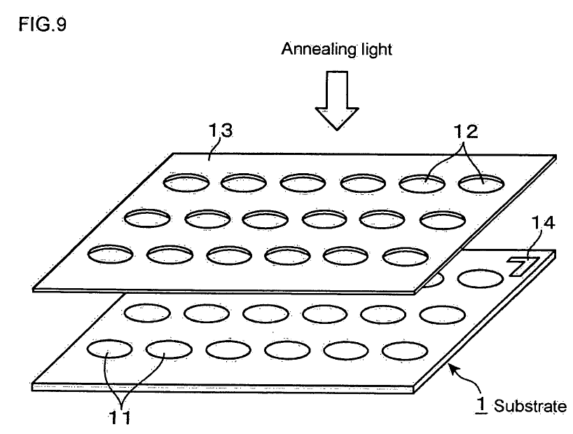

Semiconductor materials are typically allowed to exercise their functions as semiconductors by burning. The burning methods of semiconductors include heating of a substrate and application of laser light to a semiconductor. Since many of materials for use in a plastic substrate have melting points of 200° C. or lower, the heating temperature is limited in the method of heating the substrate and thus the functions of the semiconductor may not be excised sufficiently. On the other hand, in the application of the laser as shown in FIG. 9, a mask 13 is typically produced to have numerous opening portions 12 associated with numerous semiconductor formation areas 11 formed on a substrate 1, respectively, and laser light is applied through the mask 13 by a laser application device. A photo mask is used as the mask 13. When the substrate 1 is formed of a plastic substrate, however, the substrate may expand and contract or warp due to thermal expansion and contraction or the like to displace the semiconductor formation areas 11, resulting in a failure to apply the laser light. It is contemplated that an alignment mark 14 can be formed at a corner of the substrate 1 and detected to position the mask 13. However, if the substrate expands and contracts or warps, the use of the mark 14 is not an effective solution since the intervals between the opening portions 12 in the mask 13 are different from the intervals between the semiconductor formation areas 11.

### DISCLOSURE OF THE INVENTION

### Problems to be Solved by the Invention

Problems to be solved by the present invention include the abovementioned one, for example. It is thus an object of the present invention to provide a semiconductor substrate manufacture apparatus, a semiconductor substrate manufacture method, and a semiconductor substrate, in which predetermined processing such as annealing and coating application of a semiconductor material can be performed with high accuracy on numerous semiconductor formation areas formed over a wide region on a surface of a substrate having elasticity such as a plastic substrate even when the substrate expands and contracts, for example.

It is another object of the present invention to provide a semiconductor substrate manufacture apparatus, a semiconductor substrate manufacture method, and a semiconductor substrate, in which predetermined processing can be performed in a short time period on semiconductor formation areas on an expanding or contracting substrate to reduce the time taken for process, for example.

### Means for Solving the Problems

As described in claim 1, the present invention provides a semiconductor substrate manufacture apparatus performing predetermined processing on numerous semiconductor formation areas arranged over a wide region on a substrate, including: a tracking device having a light-emitting portion which applies light to a substrate surface during tracking, a light-receiving portion which receives the light applied by the light-emitting portion and reflected by the substrate surface, and a position detecting portion which detects the positions of the semiconductor formation areas on the substrate based on the spectrum or intensity of the received light; and a semiconductor processing device for performing the predetermined processing on each of the semiconductor formation areas based on the position information from the tracking device.

According to another aspect, as described in claim 17, the present invention provides a semiconductor substrate manufacture apparatus performing predetermined processing on numerous semiconductor formation areas arranged over a wide region on a substrate, including: an imaging device for taking an image of a substrate surface on which the semiconductor formation areas are arranged; a position detecting portion which detects the positions of the semiconductor formation areas on the substrate based on the information of the image of the substrate surface taken by the imaging device; and a semiconductor processing device for performing the predetermined processing on each of the semiconductor formation areas based on the position information from the position detecting device.

According to another aspect, as described in claim 22, the present invention provides a semiconductor substrate manufacture method of performing predetermined processing on numerous semiconductor formation areas arranged over a wide region on a substrate, including: a process of applying light for tracking to a substrate surface and detecting the positions of the semiconductor formation areas on the substrate based on the spectrum or intensity of the received light; and a process of performing the predetermined processing on each of the semiconductor formation areas based on the position information of the semiconductor formation areas.

According to another aspect, as described in claim 32, the present invention provides a semiconductor substrate manufacture method of performing predetermined processing on numerous semiconductor formation areas arranged over a wide region on a substrate, including: a process of taking an image of a substrate surface on which the semiconductor formation areas are arranged; a process of detecting the positions of the semiconductor formation areas on the substrate based on the information of the taken image of the substrate surface; and a process of performing the predetermined processing on each of the semiconductor formation areas based on the detected position information.

According to another aspect, as described in claim 37, the present invention provides a semiconductor substrate on which numerous semiconductor formation areas are arranged over a wide region of a surface, wherein a target for tracking is formed, the target being placed at a certain separation distance from the semiconductor formation areas and continuing along a direction in which the semiconductor formation areas are arranged.

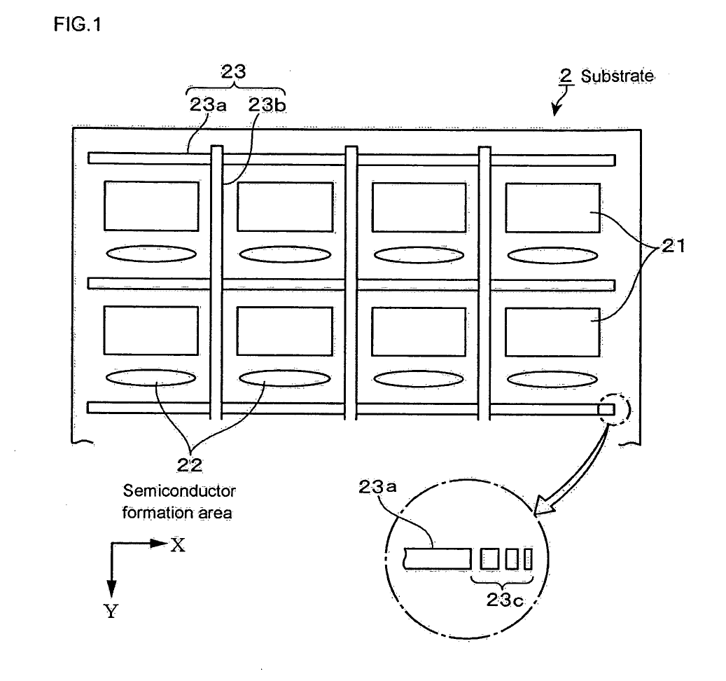

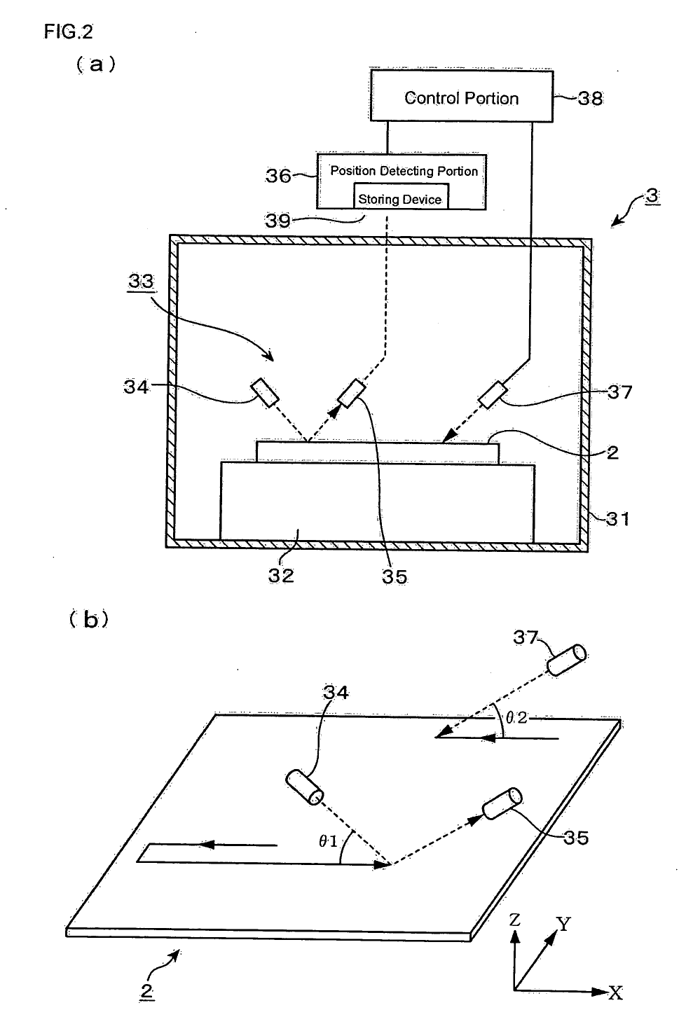

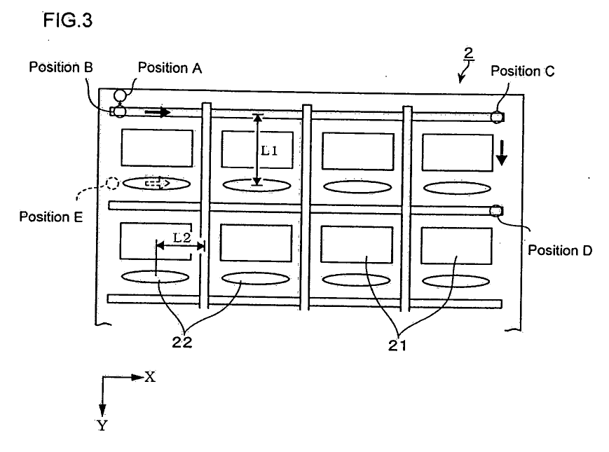

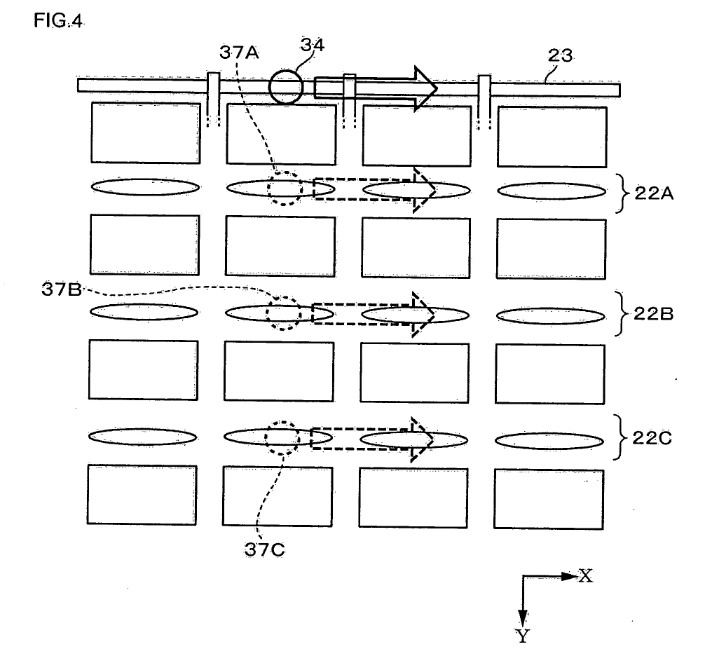

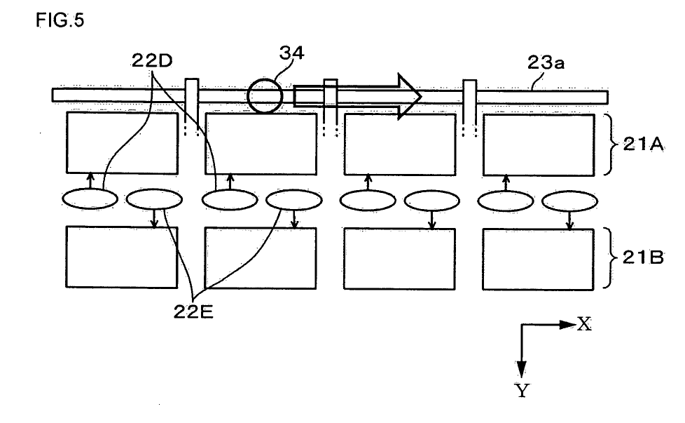

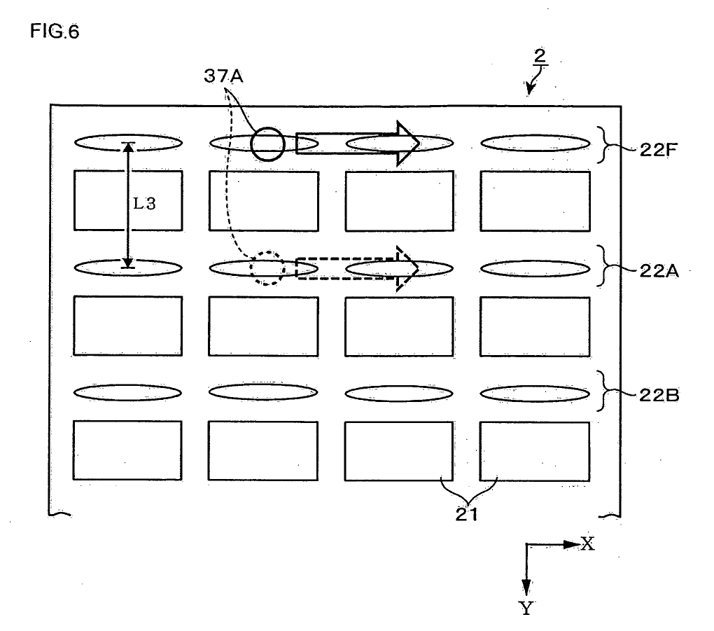

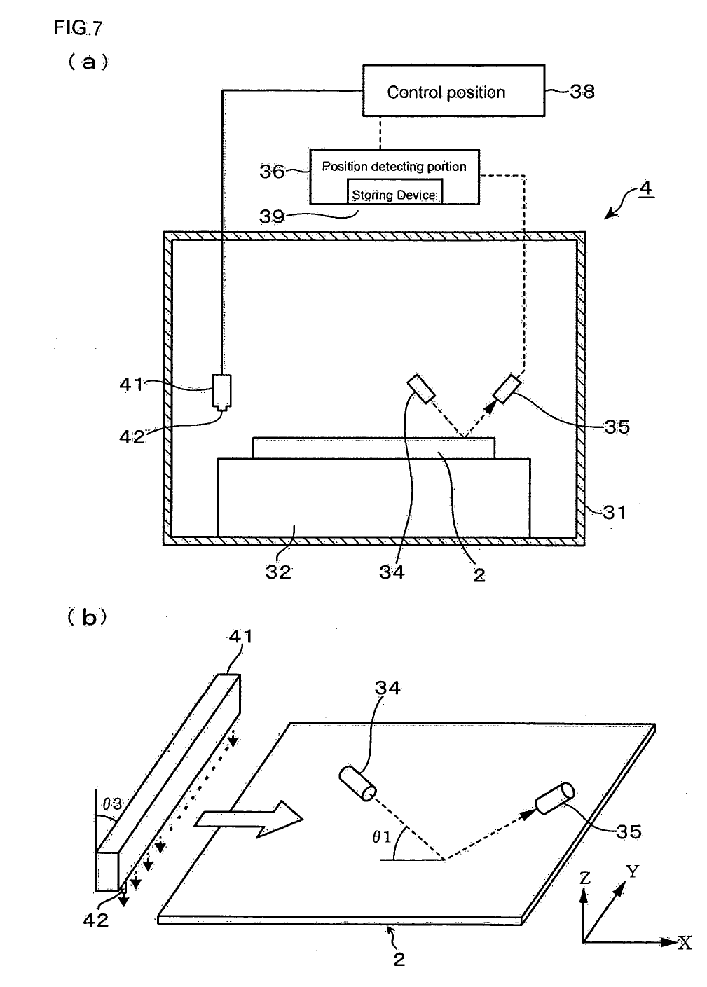

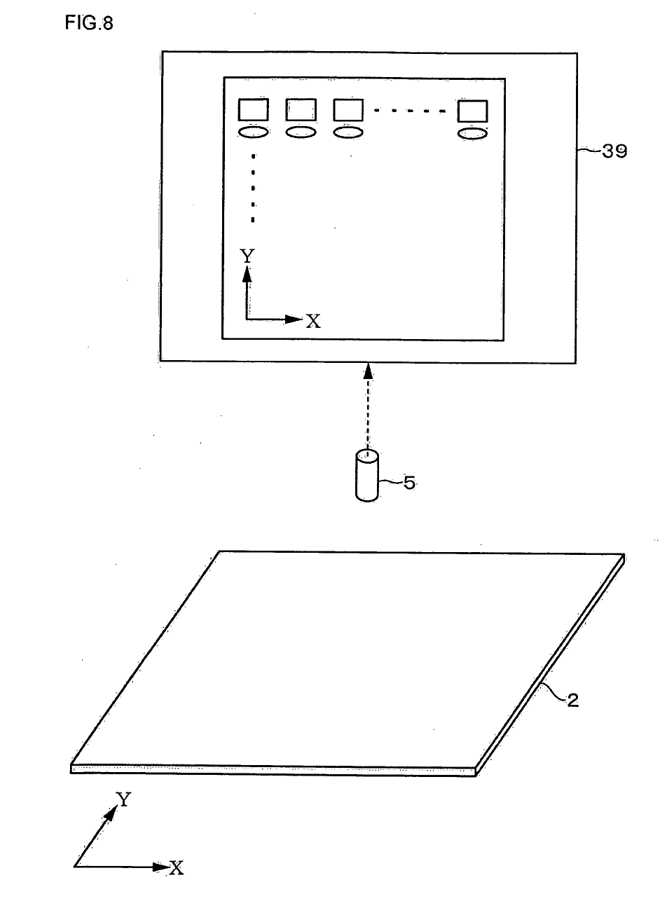

### BRIEF DESCRIPTION OF DRAWINGS

[FIG. 1] A diagram showing an example of a substrate processed by a semiconductor substrate manufacture apparatus according to an embodiment of the present invention.

[FIG. 2] A diagram showing the schematic structure of the semiconductor substrate manufacture apparatus according to an embodiment of the present invention.

[FIG. 3] A diagram schematically showing the processing of the substrate performed by the semiconductor substrate manufacture apparatus.

[FIG. 4] A diagram showing another example of the substrate processed by the semiconductor substrate manufacture apparatus.

[FIG. 5] A diagram showing yet another example of the substrate processed by the semiconductor substrate manufacture apparatus.

[FIG. 6] A diagram schematically showing the processing of the substrate performed by the semiconductor substrate manufacture apparatus.

[FIG. 7] A diagram showing the schematic structure of a semiconductor substrate manufacture apparatus according to another embodiment of the present invention.

[FIG. 8] A diagram showing the schematic structure of a semiconductor substrate manufacture apparatus according to another embodiment of the present invention.

[FIG. 9] A diagram schematically showing annealing processing in the related art.

### DESCRIPTION OF REFERENCE NUMERALS

2 SUBSTRATE
21 ORGANIC EL PORTION
22 SEMICONDUCTOR FORMATION AREA
23 ELECTRODE LINE
3 SEMICONDUCTOR SUBSTRATE MANUFACTURE APPARATUS
33 TRACKING DEVICE
34 LIGHT-EMITTING PORTION
35 LIGHT-RECEIVING PORTION
36 POSITION DETECTING PORTION
37 ANNEALING LIGHT APPLICATION DEVICE
39 STORING DEVICE
4 SEMICONDUCTOR SUBSTRATE MANUFACTURE APPARATUS
41 INKJET NOZZLE
42 DISCHARGE HOLE
5 IMAGING DEVICE

### BEST MODE FOR CARRYING OUT THE INVENTION

A semiconductor substrate manufacture apparatus according to preferred embodiments of the present invention will hereinafter be described in detail with reference to the accompanying drawings. However, the present invention is not limited to the embodiments described below.

### Embodiment 1

First, an example of a substrate to be processed by a semiconductor substrate manufacture apparatus in Embodiment 1 will be described with reference to FIG. 1. A substrate 2 is a plastic substrate of rectangular flat-plate shape having a length of 680 mm, a width of 880 mm, and a thickness of 0.2 mm, for example. Numerous pairs of organic EL portions 21 and semiconductor formation areas 22 are arranged in a matrix over a wide region of a surface of the substrate 2 as schematically shown in FIG. 1. The substrate 2 can be used as a substrate for an organic EL panel, for example, and the organic EL portion 21 formed of an organic EL element constitutes one pixel. In this case, the semiconductor formation area 22 represents an organic semiconductor layer which forms a channel portion of an organic transistor for active-driving the organic EL portion 21. Although omitted in FIG. 1, numerous sets of organic EL portions 21 and semiconductor formation areas 22 are actually arranged in several thousands of rows and several thousands of columns on the surface of the substrate 2. The substrate 2 to be processed in Embodiment 1 requires only that numerous semiconductor formation areas 21 should be formed over a wide region of the surface of the substrate 2, and the material, the shape of the substrate, the pattern shape on the substrate and the like are not limited.

The semiconductor formation area 22 is formed, for example, by patterning a photosensitive organic material deposited on the substrate 2 to form concave portions and filling the concave portions with a semiconductor material. The semiconductor material may be an organic semiconductor material or an inorganic semiconductor material. The filling of the concave portions with the semiconductor material can be performed through evaporation, coating application or the like, for example. While FIG. 1 shows the elliptic semiconductor formation area 22 as an example, the present invention it not limited thereto, and an arbitrary shape may be used such as a rectangular, linear, and pattern shape.

Electrode lines 23 are formed in a mesh arrangement to define the respective ones of the numerous sets of organic EL portions 21 and semiconductor formation areas 22. The electrode lines 23 include a power supply line, a data line, a scanning line and the like, and are formed on the substrate 2 with an electrode-line wiring process, for example. Specifically, a thin film made of a conductive material such as aluminum having a high reflectivity, for example, is formed on the substrate 2 with sputtering or the like, the thin film is patterned with photolithography and etching to form an electrode line extending in an X direction first, then an insulating film is formed to prevent an electric short circuit at intersections of the formed electrode line and an electrode line extending in a Y direction, and finally, the electrode line extending in the Y direction is formed by using a conductive material such as chromium having a low reflectivity, for example. In the example shown in FIG. 1, a power supply line 23a corresponds to the electrode line extending in a length direction (X direction) of the substrate 2, and a data line 23b corresponds to the electrode line extending in a width direction (Y direction) of the substrate 2. However, the present invention is not limited thereto.

As described later in detail, the electrode line (for example, the power supply line 23a) extending in the length direction (X-direction) of the substrate 2 is set as a target of tracking in Embodiment 1. In this case, both end portions of the electrode line 23a preferably have shapes different from that of the other area to provide light reflecting characteristics different from those of the other area. This structure allows reliable detection of the beginning end and the trailing end of the electrode line 23a in the tracking. As an example, slits 23c can be formed to have gradually reduced intervals as shown in FIG. 1. In addition, to facilitate the tracking, a reflective film may be formed or projections and depressions such as pits may be formed on a surface of the electrode line 23a serving as the target, thereby adjusting the reflectivity thereof.

As schematically shown in FIG. 2, an example of a semiconductor substrate manufacture apparatus 3 which processes the above mentioned substrate 2 includes a housing 31 which provides processing space and a substrate holding portion 32 in the housing 31. A tracking device 33 is placed opposite to a surface of the substrate 2 held on the substrate holding portion 32 with a predetermined spacing interposed between the surface of the substrate 2 and the tracking device 33. The tracking device 33 has a light-emitting portion 34 which applies semiconductor laser light for tracking having a wavelength of 635 nm, for example, at a predetermined approach angle θ1 previously set, a light-receiving portion 35 which receives the light applied by the light-emitting portion 34 and then reflected by the surface of the substrate 2, and a position detecting portion 36 which detects the target on the substrate 2 based on the spectrum or intensity of the received light to obtain the position information of the semiconductor formation areas 22. A semiconductor laser can be used as the light-emitting portion 34. A photodiode can be used as the light-receiving portion 35. A computer apparatus including a CPU can be used as the position detecting portion 36, for example. However, the light-emitting portion 34, the light-receiving portion 35, and the position detecting portion 36 are not limited thereto.

The light-emitting portion 34 and the light-receiving portion 35 are formed to be movable in a vertical direction (Z direction) by a driving mechanism (not shown) such that they are opposite to the surface of the substrate 2 with a predetermined spacing interposed therebetween. The portions 34 and 35 are also formed to be scannable in the length direction (X direction) and the width direction (Y direction) of the substrate 2. Relative movement amounts in the X direction and Y direction are detected by using a linear scale, for example, and based on the separation distance from the substrate 2 and the approach angle θ1, coordinates (X, Y) of the tracking laser light applied to the surface of the substrate 2 are calculated through computations.

The semiconductor substrate manufacture apparatus 3 also includes a semiconductor processing device for performing predetermined processing on the semiconductor formation areas 22 of the substrate 2. In Embodiment 1, as the semiconductor processing device, an annealing light application device 37 is provided for applying laser light for annealing having a wavelength of 308 nm, for example, to semiconductors formed on the semiconductor formation areas 22 at a predetermined approach angle θ2 set previously. While an excimer laser, for example, can be used as the annealing light application device 37, the present invention is not limited thereto. The annealing light application device 37 is formed to be movable in the vertical direction (Z direction) by a driving mechanism (not shown) such that the device 37 is opposite to the surface of the substrate 2 with a predetermined spacing interposed therebetween. The annealing light application device 37 is also formed to be scannable in the length direction (X direction) and the width direction (Y direction) of the substrate 2. Relative movement amounts in the X direction and Y direction are detected by using a linear scale, for example, and based on the separation distance from the substrate 2 and the approach angle θ2, the device 37 can apply laser light to the surface of the substrate 2 at arbitrary coordinates (X, Y) thereof.

The operations of the light-emitting portion 34, the light-receiving portion 35, the position detecting portion 36, and the annealing light application device described above are controlled by a control portion 38. While a computer apparatus including a CPU, for example, may be used as the control portion 38, the present invention is not limited thereto.

In detecting the positions of the semiconductor formation areas 22 on the substrate 2 through the tracking and simultaneously performing the annealing of the same substrate 2, an application area (application spot) of the tracking light preferably does not overlap with an application area (application spot) of the annealing light in order to prevent a detection error resulting from the light-receiving portion 35 receiving the annealing light. In addition, to reduce the detection error more reliably, the wavelength of the tracking light is preferably set at least 100 nm away from the wavelength of the annealing light. Furthermore, the approach angle θ1 of the tracking light is preferably set at least 10 degrees or more different from the approach angle θ2 of the annealing light. It is also preferable to provide a light filter, for example, for the light-receiving portion 35 as a shield mechanism which shields the annealing light.

The position detecting portion 36 has a memory, for example, as a storing device 39 for storing the positions of the respective semiconductor formation areas 22. Control can be performed such that the position information of the semiconductor formation areas 22 detected through the tracking is sequentially stored in the storing device 39 and that the annealing light is applied on the basis of the position information read out from the storing device 39.

Next, the operation of processing the substrate 2 shown in FIG. 1 with the semiconductor substrate manufacture apparatus 3 shown in FIG. 2 will be described.

First, the substrate 2 provided as shown in FIG. 1 with upstream processes such as a cleaning process, an electrode-line wiring process, an insulating-film forming process and the like is carried into the housing 31 through a substrate inlet (not shown) and put on the substrate holding portion 32. For example, a sucking mechanism may be provided on the surface of the substrate holding portion 32 to suck and hold the substrate 2.

Next, the light-emitting portion 34 and the light-receiving portion 35 are moved toward the surface of the substrate 2 and set to be opposite thereto with a separation distance of 5 mm, for example, from the surface of the substrate 2. Then, while the tracking light is applied, the light-emitting portion 34 and the light-receiving portion 35 scan in a horizontal direction (X direction and Y direction) to detect the electrode line (23a) serving as the target based on the spectrum or intensity of the received light. The determination of whether the target is found or not can be performed, for example by previously measuring the spectrum or intensity of light reflected by the target, storing the spectrum or intensity in the storing device 39 of the position detecting portion 36, and comparing the stored spectrum or intensity with the spectrum or intensity of the received light in the tracking. In addition, when the slits 23c are formed at the end portion of the electrode line (23a) as shown in FIG. 1, the beginning end and the trailing end of the tracking can be detected in response to a change in spectrum or intensity of the light.

An example of the tracking will be described in detail with reference to FIG. 3. First, the application position of the tracking light is set at a corner (position A) of the substrate 2. As this light-application area is scanned in the width direction (Y direction) of the substrate 2, the target is detected at a position B. Then, the substrate 2 is scanned in the length direction (X direction) to track the target. When the trailing end of the target is detected at a position C, the substrate 2 is scanned in the width direction (Y direction). The next target is detected at a position D. Then, the substrate 2 is scanned in the length direction (X direction) to track the target. The same operation is continued thereafter.

The electrode line (23a) serving as the target is separated from the semiconductor formation areas 22 by a separation distance L1. Since the separation distance L1 is previously set in design, the coordinates of the detected target can be corrected by the distance L1 to obtain the positions of the semiconductor formation areas 22 through computations. In addition, the position information of the semiconductor formation areas 22 in the X direction can be obtained through computations by detecting a change in the spectrum or intensity of the light at the position of intersection of the electrode lines 23a and 23b in the X direction and Y direction and performing correction by a separation distance L2 with the detected position used as a reference. As described earlier, when the plastic substrate is used, the substrate may expand and contract. However, the separate distances L1 and L2 are as extremely short as approximately 100 μm, so that changes in the separation distances L1 and L2 are significantly small even when the substrate 2 expands and contracts or warps. Thus, no or extremely few, if any, errors occur resulting from the correction by the separation distances L1 and L2.

While the positions of the semiconductor formation areas 22 are detected as described above, the annealing light application device 37 scans based on the detected position information to apply the annealing light to the semiconductor formation areas 22. More specifically, for example as shown in FIG. 3, the annealing light application device 37 is moved to allow the application of the annealing light to a position E corrected by the separation distance L1 from the position B where the target is detected. While the annealing light application device 37 scans in the length direction (X direction) of the substrate on which the semiconductor formation areas 22 are arranged at intervals, the device 37 sequentially applies the annealing light to the semiconductor formation areas 22. The annealing performed in this manner enables the characteristics of the semiconductor to be exercised sufficiently.

The annealing performed by the annealing light application device 37 following the tracking device 33 as described above can reduce the time taken for the processing, but the present invention is not limited thereto. Alternatively, after all the positions of the semiconductor formation areas 22 are detected, the position information may be read out from the storing device 39 to perform the annealing.

Alternatively, a plurality of annealing light application device 37 may be provided and scan simultaneously or at different times to apply the annealing light. This has the advantage that the time taken for the annealing can be shortened. As an example, as shown in FIG. 4, annealing light application devices 37A, 37B, and 37C are placed for semiconductor formation areas 22A arranged in a first row, semiconductor formation areas 22B arranged in a second row, and semiconductor formation areas 22C arranged in a third row, respectively. The annealing light application devices 37A, 37B, and 37C can scan in the length direction (X direction) of the substrate 2 to perform annealing for each of the lines. While FIG. 4 shows the example of the three annealing application devices 37A, 37B, and 37C, the present invention is not limited thereto, and more annealing application devices may be provided.

According to Embodiment 1 described above, the electrode line 23 formed over a wide region of the surface of the substrate 2 is set as the target, and the target is tracked to obtain the position information of the semiconductor formation areas 22. Even when the substrate 2 expands and contracts or warps, the positions of the numerous semiconductor formation areas 22 formed on the substrate 2 can be detected with high accuracy. Then, the annealing light is applied on the basis of the obtained position information to allow the annealing with high accuracy on the numerous semiconductor formation areas 22.

In addition, according to Embodiment 1, the annealing light is not applied to the entire substrate but applied only to the semiconductor formation areas 22 which require the annealing, so that the amount of thermal energy supplied to the substrate 2 can be requisite minimized. As a result, the functions of the semiconductor can be exercised with less damage to the substrate 2.

According to Embodiment 1, the semiconductor forming process can be simplified when an organic semiconductor material is used, for example. Specifically, the organic semiconductor material does not exercise the functions of the semiconductor and functions as an insulator unless burning is performed. Thus, a thin film of the organic semiconductor material is formed over the entire surface of a substrate, and the annealing light is applied only to an area requiring the annealing so that the functions of the semiconductor are exercised in the area. This can simplify the semiconductor forming process as compared with the case where a semiconductor is formed in a selective part with evaporation or printing. In addition, the insulating film can be provided simultaneously.

Also, according to Embodiment 1, while the target is detected by the tracking device 33, the annealing light application device 37 follows the tracking device 33 to perform the annealing, so that it is possible to perform the process from the start of the tracking to the end of the annealing on the single substrate 2 in a short time period. If the wavelength of the tracking light is set at least 100 nm or more away from the wavelength of the annealing light, or if the approach angle θ1 of the tracking light is set at least 10 degrees or more different from the approach angle θ2 of the annealing light, or if the shield mechanism which shields the annealing light is provided for the light-receiving portion 35, then detection of the annealing light by the light-receiving portion 35 is avoided and thus erroneous detection of the target can be prevented. As a result, it is possible to prevent an error in the position detection of the semiconductor formation areas 22.

In Embodiment 1, when part of the semiconductor formation area (target) formed over the wide region of the substrate 2 is detected, the detection position is sequentially switched at short time intervals (for example, at a frequency of one second or less), and the position of the application of the annealing light by the annealing light application device 37 is determined each time, then the target can be switched to a new one close to the light-application position before the distance between the detection position of the target and the light-application position is increased, that is, before a difference between the detected positions is increased due to the expansion and contraction of the substrate 2 after the tracking. In other words, the switching performed at the short time intervals and the determination of the application position of the annealing light each time as described above can maintain a relatively short distance between the target and the light-application position relative to the size of the whole substrate, thereby reducing a displacement of the application of the annealing light.

In Embodiment 1 described above, the electrode line (23a) extending in the length direction (X direction) of the substrate 2 is set as the target. The present invention is not limited thereto, and the electrode line 23b extending in the width direction (Y direction) of the substrate may be set as the target, or another component may be set as the target, or a new target may be formed. In addition, the semiconductor formation areas 22 may be set as the target. As a specific example of modification, for example as shown in FIG. 5, semiconductor formation areas 22D associated with organic EL portions 21A arranged in a first row and semiconductor formation areas 22E associated with organic EL portions 21B arranged in a second row can be placed in a line in the length direction (X direction) of the substrate 2. This structure can reduce the number of times of the scanning of the annealing light application device 37 to shorten the time taken for the annealing more reliably.

As another example of modification, for example as shown in FIG. 6, semiconductor formation areas 22F serving only as a target may be formed at an end portion (closer to the top of the sheet) in the length direction of the substrate 2. In this case, the semiconductor formation areas 22F serving as the target are tracked, and the positions of semiconductor formation areas 22A in a first row are calculated by correction with a separation distance L3. Next, the semiconductor formation areas 22A in the first row are tracked, and the positions of semiconductor formation areas 22B in a second row are calculated by correction with the separation distance L3. In FIG. 6, electrode lines are omitted.

### Embodiment 2

Embodiment 2 of the present invention will hereinafter be described with reference to FIG. 7.

As schematically shown in FIG. 7, a semiconductor substrate manufacture apparatus 4 according to Embodiment 2 has the same structure as that of the semiconductor substrate manufacture apparatus 3 of Embodiment 1 except that the former includes, as a semiconductor processing device, an inkjet nozzle 41 corresponding to a semiconductor material applying device to perform processing of applying a coating of liquid semiconductor material to each of semiconductor formation areas 22. Thus, the components identical to those of the semiconductor substrate manufacture apparatus 3 of Embodiment 1 are designated with the same reference numerals and detailed description thereof is omitted.

As shown in FIG. 7, the inkjet nozzle 41 is formed to have numerous discharge holes 42 formed in a bottom surface and arranged in a line such that discharge operation is controllable for each of the discharge holes 42. While the nozzle 41 continuously or intermittently scans in a length direction (X direction) of a substrate 2 by a driving mechanism (not shown), the liquid semiconductor material is discharged from the discharge holes 42 which pass over the semiconductor formation areas 22.

The operation of processing the substrate 2 by the semiconductor substrate manufacture apparatus 4 as formed above will be described. First, a tracking device 33 is operated as described already to obtain the position information of all the semiconductor formation areas 22 on the substrate 2 and the position information is stored in a storing device 39. Then, the nozzle 41 scans in the length direction (X-direction) of the substrate 2. The liquid semiconductor material is discharged from a predetermined one of the discharge holes 42 at a predetermined scanning position based on the position information to apply a coating of the semiconductor material to each of the semiconductor formation areas 22. The nozzle 41 may be inclined (at an inclination angle θ3) in a horizontal direction relative to a width direction (Y direction) of the substrate 2 to match the pitch of the discharge holes 42 with the intervals between the semiconductor formation areas 22 arranged in the Y direction so that the discharge holes 42 may be passed over all the semiconductor formation areas 22, or the number of the passing discharge holes 42 may be set to the maximum. In this case, since the intervals between the discharge holes 42 are previously determined in design, the inclination angle θ3 may be adjusted on the basis of the obtained position information.

In Embodiment 2, since the target formed over a wide region on the surface of the substrate 2 is tracked to obtain the position information of the semiconductor formation areas 22, the positions of all the semiconductor formation areas 22 on the substrate 22 can be detected with high accuracy even when the substrate 2 expands and contracts or warps. The liquid semiconductor material is discharged from the nozzle 41 based on the obtained position information to enable the application of the coating of the liquid semiconductor material with high accuracy to numerous semiconductor formation areas 22. The same effects can be achieved when a nozzle having a single discharge hole is used for the coating application, instead of the nozzle 41 having the numerous discharge holes 42.

In addition, the semiconductor processing device may include both of the inkjet nozzle 41 serving as the semiconductor material applying device and an annealing light application device 37 as described above. After the inkjet nozzle 41 applies the coating of the semiconductor material, the annealing light application device 37 may perform annealing. This structure can achieve both of the effects provided in Embodiments 1 and 2.

### Embodiment 3

In Embodiments 1 and 2 described above, the tracking device 33 is used to detect the target to obtain the position information of the semiconductor formation areas 22. The present invention is not limited thereto. For example, as shown schematically in FIG. 8, an imaging device 5 such as a CCD camera may be used to take an image of a surface of a substrate 22, and the position information of semiconductor formation areas 22 may be obtained by data analysis of the image of the surface of the substrate. In this case, one or both of an annealing light application device 37 and an inkjet nozzle 41 can be provided as a semiconductor processing device. This structure allows highly accurate detection of the positions of the semiconductor formation areas 22 formed over a wide region of the substrate 2 to achieve the same effects as those in Embodiments 1 and 2. In addition, the use of the imaging device 5 to detect the positions can reduce the time taken for obtaining the position information.

As described above, according to the present invention, the semiconductor substrate manufacture apparatus performing the predetermined processing on the numerous semiconductor formation areas arranged over the wide region on the substrate, including: the tracking device having the light-emitting portion which applies the light to the substrate surface during the tracking, the light-receiving portion which receives the light applied by the light-emitting portion and reflected by the substrate surface, and the position detecting portion which detects the positions of the semiconductor formation areas on the substrate based on the spectrum or intensity of the received light; and the semiconductor processing device for performing the predetermined processing on each of the semiconductor formation areas based on the position information from the tracking device. Even when the substrate expands and contracts or warps, the positions of the numerous semiconductor formation areas formed over the wide region on the substrate surface can be detected with high accuracy. The semiconductor processing device performs the processing based on the obtained position information to allow the highly accurate processing on the numerous semiconductor formation areas.

According to the present invention, the semiconductor substrate manufacture apparatus performing the predetermined processing on the numerous semiconductor formation areas arranged over the wide region on the substrate, including: the imaging device for taking the image of the substrate surface on which the semiconductor formation areas are arranged; the position detecting portion which detects the positions of the semiconductor formation areas on the substrate based on the information of the image of the substrate surface taken by the imaging device; and the semiconductor processing device for performing the predetermined processing on each of the semiconductor formation areas based on the position information from the position detecting device. Thus, the same effects as those in the abovementioned aspect of the present invention can be achieved, and the time taken for the position detection can be shortened.

1-39. (canceled)

40. A semiconductor substrate manufacture apparatus performing predetermined processing on numerous semiconductor formation areas arranged over a wide region on a substrate, comprising:
tracking device having a light-emitting portion which applies light to a substrate surface during tracking of a target formed on the substrate, the target being placed at a certain separation distance from the semiconductor formation areas, continuing along a direction in which the semiconductor formation areas are arranged, and having an end portion which has a shape different from a shape of the other area of the target, a light-receiving portion which receives the light applied by the light-emitting portion and reflected by the substrate surface, and a position detecting portion which detects positions of the semiconductor formation areas on the substrate based on a spectrum or intensity of the received light; and
semiconductor processing device for performing the predetermined processing on each of the semiconductor formation areas based on position information from the tracking device.

41. The semiconductor substrate manufacture apparatus according to claim 40, wherein the substrate is a plastic substrate.

42. The semiconductor substrate manufacture apparatus according to claim 40, wherein the continuing target is tracked, and simultaneously, positions of a plurality of semiconductor formation areas arranged in a direction orthogonal to a direction of the tracking are calculated.

43. The semiconductor substrate manufacture apparatus according to claim 40, wherein at least one electrode line of a power supply line, a data line, and a scanning line formed on the substrate is used as the target.

44. The semiconductor substrate manufacture apparatus according to claim 40, further comprising storing device for storing the position information of each of the semiconductor formation areas, wherein the position information is read out from the storing device and the semiconductor processing device performs the processing.

45. The semiconductor substrate manufacture apparatus according to claim 40, wherein part of the semiconductor formation areas formed over the wide region on the substrate or of the target is detected, a position of the detection is sequentially switched at short time intervals, and a position of the processing by the semiconductor processing device is determined each time.

46. The semiconductor substrate manufacture apparatus according to claim 45, wherein the detection position is switched at a frequency of one second or less.

47. The semiconductor substrate manufacture apparatus according to claim 40, wherein a plurality of the semiconductor processing device are provided for the single tracking device.

48. The semiconductor substrate manufacture apparatus according to claim 40, wherein the semiconductor processing device is annealing light application device for applying annealing light to a semiconductor formed in the semiconductor formation area.

49. The semiconductor substrate manufacture apparatus according to claim 48, wherein the annealing light application device applies the annealing light while the annealing light application device follows the tracking device.

50. The semiconductor substrate manufacture apparatus according to claim 49, wherein a wavelength of the light for tracking applied by the light-emitting portion is at least 100 nm or more away from a wavelength of the annealing light applied by the annealing light application device.

51. The semiconductor substrate manufacture apparatus according to claim 49, wherein an approach angle of the light for tracking is at least 10 degrees or more different from an approach angle of the annealing light.

52. The semiconductor substrate manufacture apparatus according to claim 49, wherein the light-receiving portion of the tracking device includes a shield mechanism which shields the annealing light.

53. The semiconductor substrate manufacture apparatus according to claim 40, wherein the semiconductor processing device is an inkjet nozzle which applies a coating of a liquid semiconductor material to the semiconductor formation areas.

54. A semiconductor substrate manufacture method of performing predetermined processing on numerous semiconductor formation areas arranged over a wide region on a substrate, comprising:
a process of applying light for tracking to a target formed on the substrate, the target being placed at a certain separation distance from the semiconductor formation areas, continuing along a direction in which the semiconductor formation areas are arranged, and having an end portion which has a shape different from a shape of the other area of the target, detecting positions of the semiconductor formation areas on the substrate based on a spectrum or intensity of the received light, and when the end portion of the target is detected in response to a change in the spectrum or intensity of the received light, switching the target to another target and performing tracking; and
a process of performing the predetermined processing on each of the semiconductor formation areas based on position information of the semiconductor formation areas.

55. The semiconductor substrate manufacture method according to claim 54, wherein the substrate is a plastic substrate.

56. The semiconductor substrate manufacture method according to claim 54, wherein the continuing target is tracked, and simultaneously, positions of a plurality of semiconductor formation areas arranged in a direction orthogonal to a direction of the tracking are calculated.

57. The semiconductor substrate manufacture method according to claim 54, wherein at least one electrode line of a power supply line, a data line, and a scanning line formed on the substrate is used as the target to perform the tracking.

58. The semiconductor substrate manufacture method according to claim 54, wherein part of the semiconductor formation areas formed over the wide region on the substrate or of the target is detected, a position of the detection is sequentially switched at short time intervals, and a position of the processing by the semiconductor processing device is determined each time.

59. The semiconductor substrate manufacture method according to claim 58, wherein the detection position is switched at a frequency of one second or less.

60. The semiconductor substrate manufacture method according to claim 54, wherein the performing predetermined processing is an annealing processing in which annealing light is applied to a semiconductor formed in each of the semiconductor formation areas.

61. The semiconductor substrate manufacture method according to claim 54, wherein the predetermined processing is a applying a coating of a liquid semiconductor material to each of the semiconductor formation areas by using an inkjet nozzle.

62. A semiconductor substrate on which numerous semiconductor formation areas are arranged over a wide region of a surface,
wherein a target for tracking is formed, the target being placed at a certain separation distance from the semiconductor formation areas, continuing along a direction in which the semiconductor formation areas are arranged, and having an end portion which has a shape different from a shape of the other area of the target.

63. The semiconductor substrate according to claim 62, wherein at least one electrode line of a power supply line, a data line, and a scanning line formed on the substrate doubles as the target.
